(19) United States
(12) Patent Application Publication
(10) Pub. No.: US 2008/0061901 A1
(43) Pub. Date: Mar. 13, 2008

(54) Apparatus and Method for Switching Between Matching Impedances

(76) Inventor: Jack Arthur Gilmore, Fort Collins, CO (US)

Correspondence Address: NEUGEBOREN LAW FIRM PC, 1035 PEARL STREET, SUITE 400, BOULDER, CO, 80302, US

(21) Appl. No.: 11/531,665

(22) Filed: Sep. 13, 2006

(51) Int. Cl. H03H 7/38

(52) U.S. Cl. 333/17.3

(57) ABSTRACT

An apparatus and method for switching between matching impedances is described. One illustrative embodiment matches a first predetermined value of a dynamically varying load impedance to a predetermined source impedance and causes a phase shift between the source and the load that permits a second predetermined value of the dynamically varying load impedance to be matched to the predetermined source impedance by the addition, between the source and the load, of a single reactive element. Determining whether the dynamically varying impedance of the load is the first predetermined value or the second predetermined value permits the single reactive element to be omitted from or included in an impedance-matching circuit as needed to match the dynamically varying impedance of the load to the predetermined source impedance.

### FIELD OF THE INVENTION

The present invention relates to impedance matching in electrical circuits. In particular, but not by way of limitation, the present invention relates to apparatuses and methods for switching between matching impedances to match a dynamically varying load impedance to a source impedance.

### BACKGROUND OF THE INVENTION

Often, an impedance-matching circuit is called on to match to a predetermined source impedance a load impedance that varies dynamically among two or more distinct values. Such dynamically varying load impedance can occur, for example, in a sputtering magnetron. In some sputtering magnetrons, a magnetic field is switched among two or more configurations to control the distribution of plasma in the plasma chamber to more evenly coat the substrate with the target material. These different magnetic field configurations cause the impedance of the load—the plasma—to vary among two or more distinct values. In some cases, the load impedance changes in as little as 30 ms.

One conventional approach to matching a dynamically varying load impedance is to employ a matching network that includes two variable elements, usually capacitors. One variable element controls the magnitude of the matching impedance; the other, the reactive component. Due to the “crosstalk” between the two variable elements, an input measurement device is normally required. The input measurement device is coupled to analog circuitry that drives servo motors to adjust the variable elements. More recently, impedance-matching circuits have been developed that use an analog-to-digital (A/D) converter to measure input voltage and current and the phase between the input voltage and current to compute the actual input impedance of the matching network. In these more modern impedance-matching circuits, digital stepper motors are often used to adjust the variable elements. Unfortunately, mechanical adjustment of variable elements does not work well with load-impedance changes that occur within, e.g., 30 ms.

In applications requiring rapid switching between two or more matching impedances, PIN-diode switches can be used to switch components in and out of the matching network. In an application such as a sputtering magnetron, however, the difficulty arises that the two or more distinct load impedances do not necessarily lie in any particular trajectory on a Smith Chart, complicating the task of matching all of the distinct load impedance values.

It is thus apparent that there is a need in the art for an improved apparatus and method for switching between matching impedances.

### SUMMARY OF THE INVENTION

Illustrative embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents, and alternative constructions that fall within the spirit and scope of the invention as expressed in the claims.

The present invention can provide an apparatus and method for switching between matching impedances. One illustrative embodiment is an electrical apparatus to switch between matching impedances, comprising a switched element configured to be coupled selectively to the electrical apparatus; a matching network configured to cause an input impedance of the electrical apparatus to match a predetermined source impedance when an impedance of a load connected with an output of the electrical apparatus is a first predetermined value and the switched element is decoupled from the electrical apparatus; a phase-shift network configured to cause the input impedance of the electrical apparatus to match the predetermined source impedance when the impedance of the load connected with the output of the electrical apparatus is a second predetermined value and the switched element is coupled to the electrical apparatus; a sensor configured to distinguish between the impedance of the load being the first predetermined value and the impedance of the load being the second predetermined value; and a control element configured to decouple the switched element from the electrical apparatus when the sensor determines that the impedance of the load is the first predetermined value and to couple the switched element to the electrical apparatus when the sensor determines that the impedance of the load is the second predetermined value.

Another illustrative embodiment is a method, comprising matching a first predetermined value of the dynamically varying load impedance to the predetermined source impedance and causing a phase shift between the source and the load that permits a second predetermined value of the dynamically varying load impedance to be matched to the predetermined source impedance by the addition, between the source and the load, of a single reactive element. These and other embodiments are described in further detail herein.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings, wherein:

FIG. 1 is a block diagram of an impedance-matching circuit in accordance with an illustrative embodiment of the invention;

FIG. 2 is a block diagram of an impedance-matching circuit in accordance with another illustrative embodiment of the invention;

FIG. 3 is a block diagram of an impedance-matching circuit in accordance with yet another illustrative embodiment of the invention;

FIGS. 4A-4C are simplified Smith Charts showing how an illustrative embodiment of the invention can be used to match two or more distinct load impedance values of a dynamically varying load to a predetermined source impedance;

FIG. 5 is a block diagram of an electrical apparatus that includes an impedance-matching circuit in accordance with an illustrative embodiment of the invention;

FIG. 6 is a flowchart of a method for matching a dynamically varying impedance of a load to a predetermined source impedance of a source in accordance with an illustrative embodiment of the invention;

FIG. 7 is a flowchart of a method for matching a dynamically varying impedance of a load to a predetermined source impedance of a source in accordance with another illustrative embodiment of the invention;

FIG. 8 is a schematic diagram of a shunt-switched-element implementation of an impedance-matching circuit in accordance with an illustrative embodiment of the invention; and

FIG. 9 is a schematic diagram of a series-switched-element implementation of an impedance-matching circuit in accordance with an illustrative embodiment of the invention.

### DETAILED DESCRIPTION

In an illustrative embodiment, a first predetermined load impedance value is matched to a predetermined source impedance. A phase shift is introduced between the source and the load that permits a second predetermined load impedance value to be matched to the predetermined source impedance by the addition, between the source and the load, of a single reactive element. The first and second predetermined load impedance values are matched by selectively omitting and including, respectively, the single reactive element. The occurrence of the first and second load impedance values is distinguished, and the single reactive element is omitted or included as needed to match the dynamically varying impedance of the load to the predetermined source impedance. In some embodiments, the single reactive element is in a shunt configuration. In other embodiments, the single reactive element is in a series configuration. Note that, herein, the labels “first” and “second” in reference to the predetermined load impedance values are arbitrary.

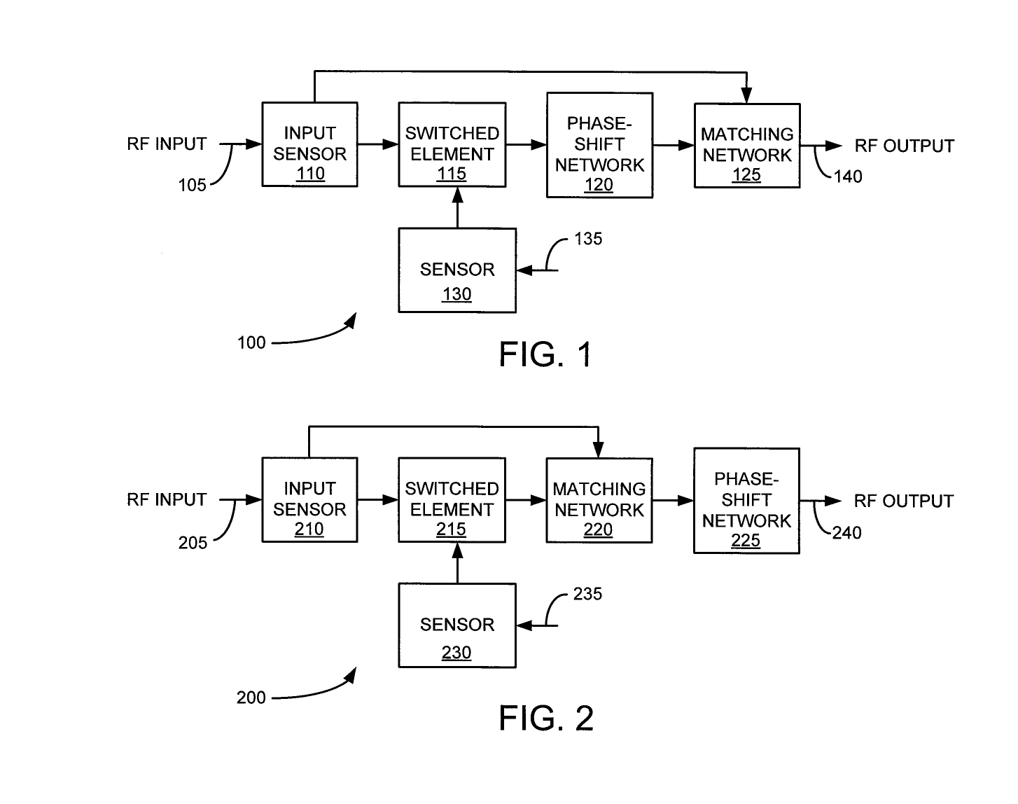

Referring now to the drawings, where like or similar elements are designated with identical reference numerals throughout the several views, and referring in particular to FIG. 1, it is a block diagram of an impedance-matching circuit 100 in accordance with an illustrative embodiment of the invention. Impedance-matching circuit 100 dynamically matches to a predetermined source impedance a load (not shown in FIG. 1) whose impedance varies between two predetermined values. The predetermined source impedance can be any value. One typical value in sputtering magnetron applications is a 50-ohm resistance (no reactive component).

In FIG. 1, a radio-frequency (RF) input 105 is fed to impedance-matching circuit 100 via input sensor 110. Impedance-matching circuit 100 also includes switched element 115, phase-shift network 120, matching network 125, and sensor 130. Sensor 130 is configured to monitor a signal 135 to determine the current state of the load with which the output of impedance-matching circuit 100 (RF output 140) is connected.

In embodiments in which matching network 125 is a variable matching network, input sensor 110 controls the variable matching network. In embodiments employing a fixed matching network, input sensor 110 is omitted. Matching network 125 is configured to match a first of the two distinct load impedance values to the source impedance when switched element 115 is switched out of (decoupled from) impedance-matching circuit 100. Techniques for designing such a matching network are well known in the impedance-matching art and are not repeated herein. Matching network 125 has any of a variety of different topologies, including, without limitation, high-pass or low-pass “T,” high-pass or low-pass “Pi,” L-match, and gamma-match.

Phase-shift network 120 is configured such that, when switched element 115 is switched in (coupled to impedance-matching circuit 100), the second of the two load impedance values is matched to the source impedance. This will be explained more fully below. Phase-shift network 120, depending on the embodiment, has any of a variety of topologies, including, without limitation, high-pass or low-pass “T” or “Pi.”

Sensor 130 distinguishes between the first and second values of the load impedance. In a sputtering magnetron embodiment, for example, sensor 130 monitors the state of the magnetic field used to distribute the plasma in the plasma chamber. When the magnetic field is in the first state, the load impedance of the plasma has a corresponding first value. When the magnetic field is in the second state, the load impedance of the plasma has a corresponding second value. The output of sensor 130 is used to control the state (switched in or switch out) of switched element 115. In one illustrative embodiment, the output of sensor 130 is fed to a bias network that controls switched element 115 (not shown in FIG. 1). When sensor 130 detects the first load-impedance value, the output of sensor 130 causes switched element 115 to be decoupled from impedance-matching circuit 100. When sensor 130 detects the second load impedance value, the output of sensor 130 causes switched element 115 to be coupled to impedance-matching circuit 100.

Switched element 115 is a reactive element, a capacitor or an inductor, that can be selectively coupled to or decoupled from impedance-matching circuit 100 in accordance with the output of sensor 130. Switched element 115 can be switched in and out of impedance-matching circuit 100 through the use of, e.g., a PIN diode controlled by an appropriate biasing network. In one embodiment, switched element 115 is a shunt element. In another embodiment, switched element 115 is a series element.

FIG. 2 is a block diagram of an impedance-matching circuit 200 in accordance with another illustrative embodiment of the invention. In the embodiment shown in FIG. 2, phase-shift network 225 is between matching network 220 and the load (not shown in FIG. 2) with which RF output 240 is connected.

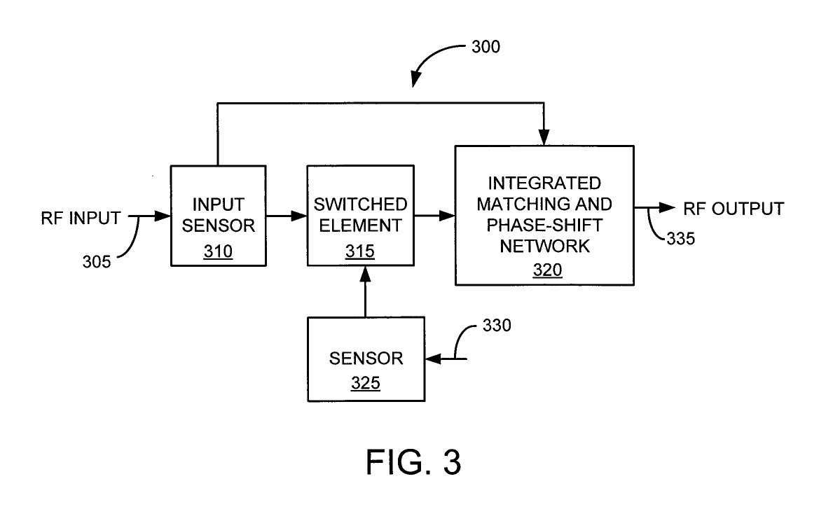

FIG. 3 is a block diagram of an impedance-matching circuit 300 in accordance with yet another illustrative embodiment of the invention. In the embodiment shown in FIG. 3, the phase-shift network and the matching network are integrated (see 320).

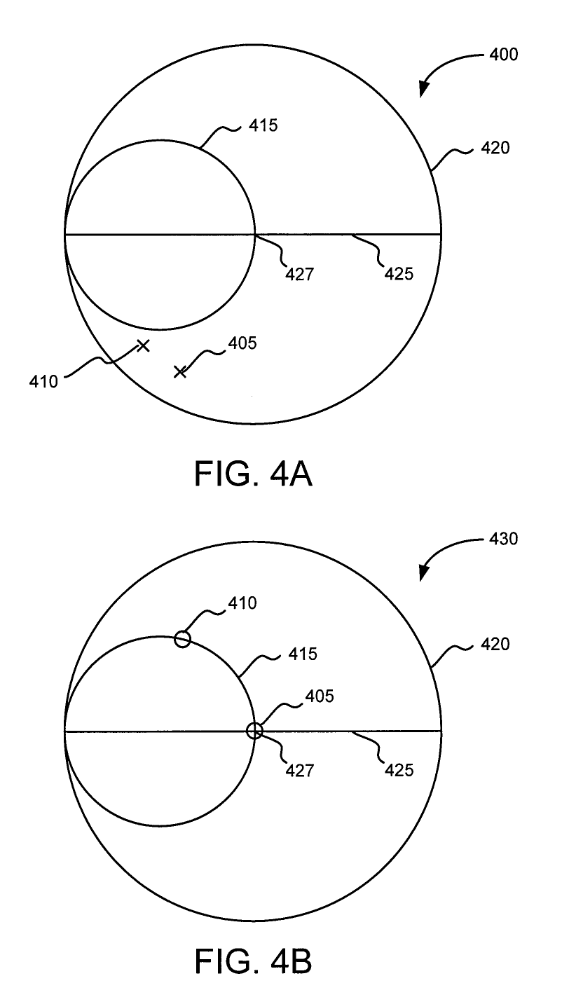

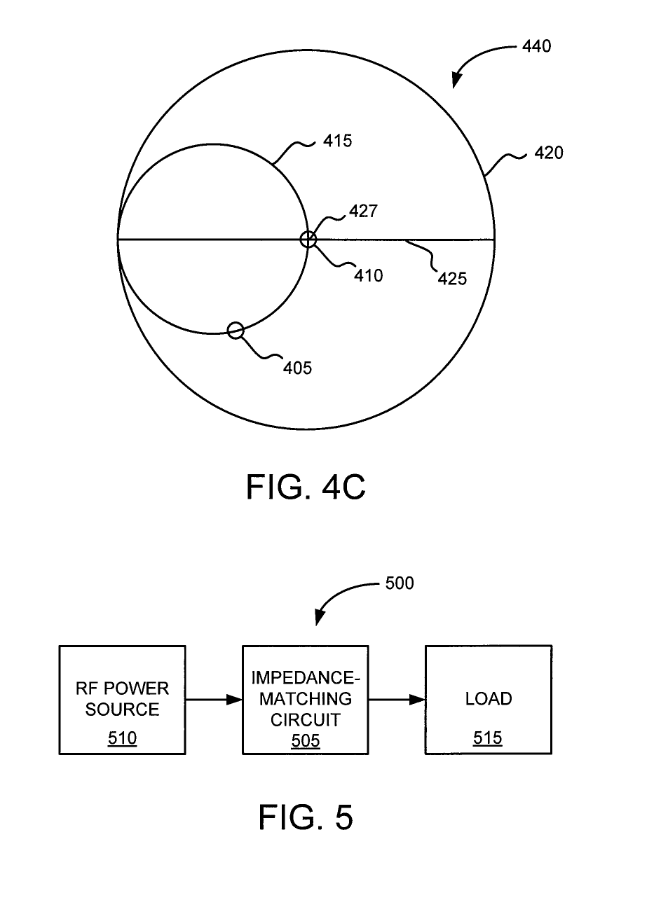

FIGS. 4A-4C are simplified Smith Charts showing how an illustrative embodiment of the invention can be used to match two or more distinct load impedance values of a dynamically varying load to a predetermined source impedance.

In the simplified Smith Chart 400 of FIG. 4A, first load-impedance value 405 and second load-impedance value 410 (marked with “X's” in FIG. 4A) are plotted. Circle 415 corresponds to all impedances on Smith Chart 400 that have the same real part as the predetermined source impedance (e.g., 50 ohms). The center of outer circle 420 (427), where circle 415 intersects horizontal axis 425, is the “match point” that corresponds to an impedance that exactly matches the source impedance. Those skilled in the art are aware that, to maximize the power delivered to the load and to eliminate reflections from the load, the load impedance must be the complex conjugate of the source impedance. Where the source impedance is purely real (resistive), the goal of an impedance-matching circuit is to make the load look like a resistance equal to the source resistance.

In the simplified Smith Chart 430 of FIG. 4B, a matching network matches to the source impedance the first load-impedance value 405 (marked with a circle in FIG. 4B) when a single switched reactive element is decoupled from the impedance-matching circuit. A phase-shift network in the impedance-matching circuit also places the second load-impedance value 410 (marked with a circle in FIG. 4B) on a trajectory (circle 415) that permits the second load-impedance value 410 to be matched to the source impedance by coupling to the impedance-matching circuit the single switched reactive element.

In the simplified Smith Chart 440 of FIG. 4C, the single switched reactive element is coupled to the impedance-matching circuit to match the second load-impedance value 410 to the source impedance.

The phase-shift network (see, e.g., 120, 225, and 320 in FIGS. 1, 2, and 3, respectively) and the matching network (see, e.g., 125, 220, and 320 in FIGS. 1, 2, and 3, respectively) can be designed with the aid of, for example, an interactive Smith Chart software application such as WINSMITH produced by Noble Publishing. The design of such matching and phase-shift networks typically involves some trial and error, and an interactive graphical tool such as WINSMITH speeds the process.

The principles of the invention illustrated in the various embodiments described above can be generalized to more than two load-impedance values. For example, an additional phase-shift network can be added to the impedance-matching circuit to match a third load-impedance value to the predetermined source impedance. The design of such an impedance-matching circuit, however, becomes more complex and costly with each additional distinct load-impedance value beyond two.

FIG. 5 is a block diagram of an electrical apparatus 500 that includes an impedance-matching circuit in accordance with an illustrative embodiment of the invention. In FIG. 5, impedance-matching circuit 505 couples RF power source 510 to load 515. In one embodiment, electrical apparatus 500 is a sputtering magnetron, and load 515 is a plasma whose impedance varies among at least two distinct values.

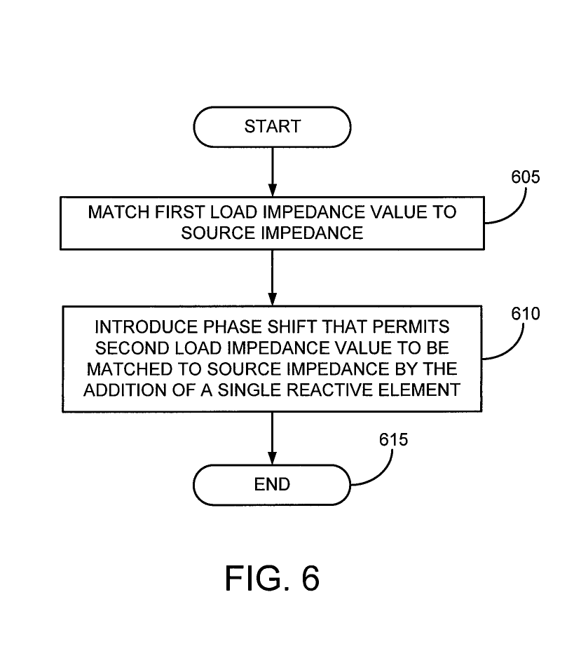

FIG. 6 is a flowchart of a method for matching a dynamically varying impedance of a load to a predetermined source impedance of a source in accordance with an illustrative embodiment of the invention. At 605, a first load-impedance value 405 is matched to a predetermined source impedance as explained above. At 610, a phase shift is introduced between the source and the load that permits a second load-impedance value 410 to be matched to the predetermined source impedance by the addition of a single reactive element. The process terminates at 615.

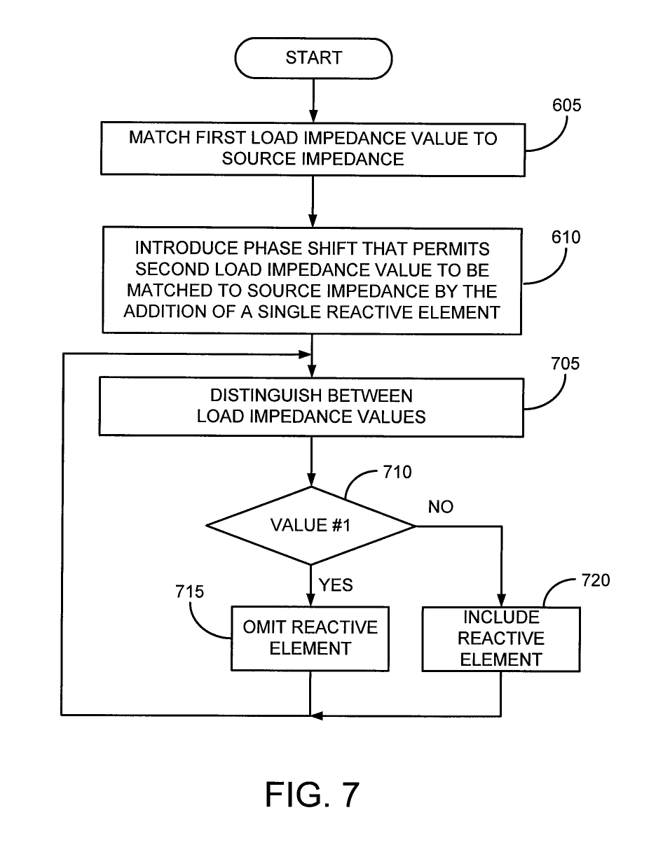

FIG. 7 is a flowchart of a method for matching a dynamically varying impedance of a load to a predetermined source impedance of a source in accordance with another illustrative embodiment of the invention. In FIG. 7, the process proceeds as in FIG. 6 through Block 610. At 705, the present load-impedance value is determined by distinguishing between the first and second load-impedance values. If the first load-impedance value is present at 710, the single reactive element is omitted, at 715, from an impedance-matching circuit. Otherwise, if the second load-impedance value is present at 710, the single reactive element is included in the impedance-matching circuit at 720. As discussed above, the labels “first” and “second” in reference to the load-impedance values are arbitrary.

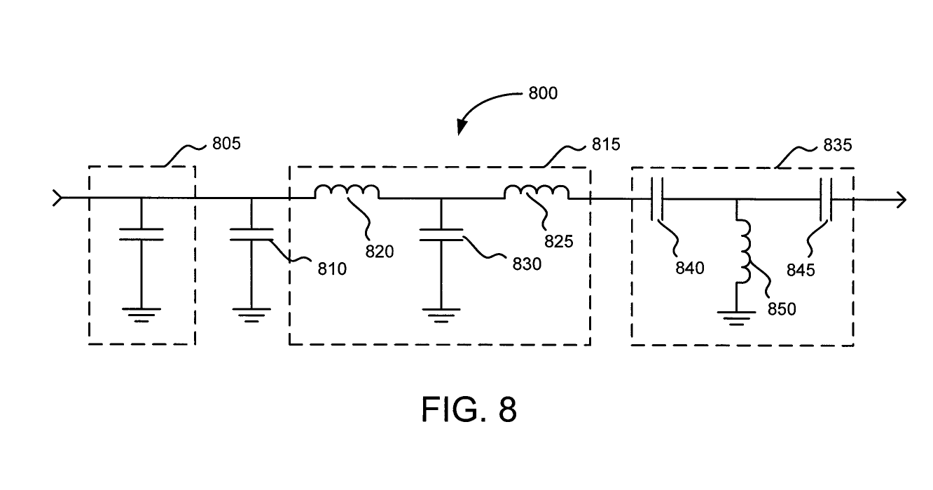

FIG. 8 is a schematic diagram of a shunt-switched-element implementation of an impedance-matching circuit 800 in accordance with an illustrative embodiment of the invention. Impedance-matching circuit 800 includes switched element 805, a shunt capacitor in this embodiment. For simplicity, additional components for switching switched element 805 in and out of impedance-matching circuit 800 (e.g., a PIN diode and its associated bias network) have been omitted from FIG. 8. Impedance-matching circuit 800, in this particular embodiment, also includes an additional fixed shunt capacitor 810. Phase-shift network 815 has a “T” topology made up of two series inductors 820 and 825 and a shunt capacitor 830. Matching network 835, which also has a “T” topology, is made up of two series capacitors 840 and 845 and shunt inductor 850. The circuit shown in FIG. 8 is merely one of many possible implementations.

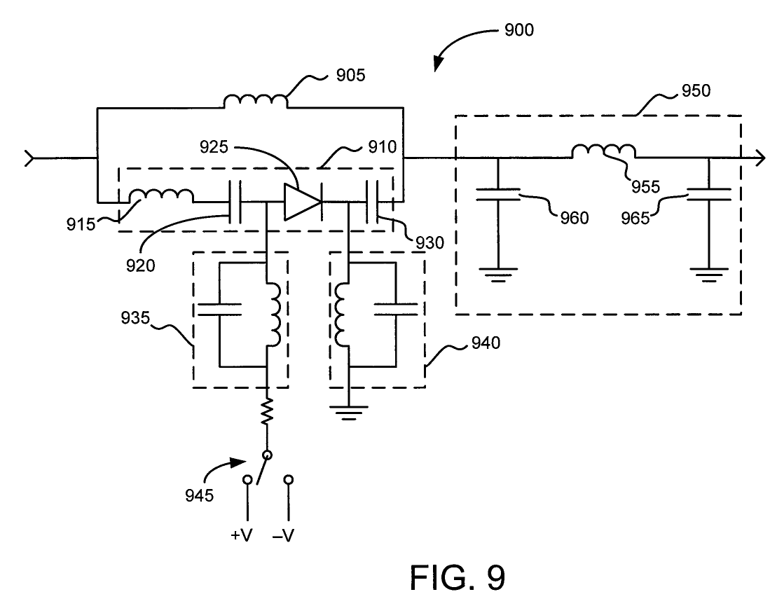

FIG. 9 is a schematic diagram of a series-switched-element implementation of an impedance-matching circuit 900 in accordance with an illustrative embodiment of the invention. Impedance-matching circuit 900 includes fixed series inductor 905 in parallel with switched element 910. Switched element 910, in this embodiment, includes inductor 915, blocking capacitor 920, PIN diode 925, and blocking capacitor 930. PIN diode 925 is controlled by resonant tank circuits 935 and 940, which are tuned to the input RF frequency. Resonant tank circuit 935 is connected with switch 945, which selectively couples resonant tank circuit 935 to a positive or a negative voltage (+V or −V in FIG. 9) to turn on or turn off, respectively, PIN diode 925. Phase-shift network 950, in this embodiment, has a “Pi” topology and is made up of a series inductor 955 and shunt capacitors 960 and 965. Phase-shift network 950 can be followed by a suitable matching network as shown in FIGS. 1 and 8, or phase-shift network 950, in some embodiments, doubles as the matching network.

In conclusion, the present invention provides, among other things, an apparatus and method for switching between matching impedances. Those skilled in the art can readily recognize that numerous variations and substitutions may be made in the invention, its use and its configuration to achieve substantially the same results as achieved by the embodiments described herein. Accordingly, there is no intention to limit the invention to the disclosed illustrative forms. Many variations, modifications and alternative constructions fall within the scope and spirit of the disclosed invention as expressed in the claims.

What is claimed is:

1. An electrical apparatus to switch between matching impedances, comprising:
a switched element configured to be coupled selectively to the electrical apparatus;
a matching network configured to cause an input impedance of the electrical apparatus to match a predetermined source impedance when an impedance of a load connected with an output of the electrical apparatus is a first predetermined value and the switched element is decoupled from the electrical apparatus;
a phase-shift network configured to cause the input impedance of the electrical apparatus to match the predetermined source impedance when the impedance of the load connected with the output of the electrical apparatus is a second predetermined value and the switched element is coupled to the electrical apparatus;
a sensor configured to distinguish between the impedance of the load being the first predetermined value and the impedance of the load being the second predetermined value; and
a control element configured to:
decouple the switched element from the electrical apparatus when the sensor determines that the impedance of the load is the first predetermined value; and
couple the switched element to the electrical apparatus when the sensor determines that the impedance of the load is the second predetermined value.

2. The electrical apparatus of claim 1, wherein the phase-shift network is between the switched element and the matching network.

3. The electrical apparatus of claim 1, wherein the phase-shift network is between the matching network and the load.

4. The electrical apparatus of claim 1, wherein the phase-shift network is integrated with the matching network.

5. The electrical apparatus of claim 1, wherein the matching network is a variable matching network, the electrical apparatus further comprising:
an input sensor at an input of the electrical apparatus, the input sensor being configured to control the variable matching network.

6. The electrical apparatus of claim 1, wherein the switched element is in a shunt configuration.

7. The electrical apparatus of claim 1, wherein the switched element is in a series configuration.

8. The electrical apparatus of claim 1, wherein the switched element is one of a capacitor and an inductor.

9. The electrical apparatus of claim 1, wherein the phase-shift network has one of a T and a Pi topology and the phase-shift network has one of a high-pass frequency response and a low-pass frequency response.

10. The electrical apparatus of claim 1, wherein the matching network has one of a high-pass T, low-pass T, L-match, and gamma-match topology.

11. The electrical apparatus of claim 1, wherein the predetermined source impedance is a 50-ohm resistance.

12. An electrical apparatus to switch between matching impedances, comprising:
means for matching an input impedance of the electrical apparatus to a predetermined source impedance when an impedance of a load connected with an output of the electrical apparatus is a first predetermined value and a reactive element is decoupled from the electrical apparatus;
means for causing the input impedance of the electrical apparatus to match the predetermined source impedance when the impedance of the load connected with the output of the electrical apparatus is a second predetermined value and the reactive element is coupled to the electrical apparatus;
means for distinguishing between the impedance of the load being the first predetermined value and the impedance of the load being the second predetermined value; and
means for selectively coupling the reactive element to the electrical apparatus, the means for selectively coupling being configured to:
decouple the reactive element from the electrical apparatus when the means for distinguishing between the impedance of the load being the first predetermined value and the impedance of the load being the second predetermined value determines that the impedance of the load is the first predetermined value; and
couple the reactive element to the electrical apparatus when the means for distinguishing between the impedance of the load being the first predetermined value and the impedance of the load being the second predetermined value determines that the impedance of the load is the second predetermined value.

13. An electrical apparatus, comprising:
a radio-frequency (RF) power supply having a predetermined source impedance;
a load having a dynamically varying impedance; and
an impedance-matching circuit coupling electrically the RF power supply to the load, the impedance-matching circuit including:
a switched element configured to be coupled selectively to the impedance-matching circuit;
a matching network configured to cause an input impedance of the impedance-matching circuit to match the predetermined source impedance when the dynamically varying impedance of the load is a first predetermined value and the switched element is decoupled from the impedance-matching circuit;
a phase-shift network configured to cause the input impedance of the impedance-matching circuit to match the predetermined source impedance when the dynamically varying impedance of the load is a second predetermined value and the switched element is coupled to the impedance-matching circuit;
a sensor configured to distinguish between the dynamically varying impedance of the load being the first predetermined value and the dynamically varying impedance of the load being the second predetermined value; and
a control element configured to:
decouple the switched element from the impedance-matching circuit when the sensor determines that the impedance of the load is the first predetermined value; and
couple the switched element to the impedance-matching circuit when the sensor determines that the impedance of the load is the second predetermined value.

14. The electrical apparatus of claim 13, wherein the electrical apparatus is a sputtering magnetron and the load is a plasma.

15. A method for matching a dynamically varying impedance of a load to a predetermined source impedance of a source, the method comprising:
matching a first predetermined value of the dynamically varying load impedance to the predetermined source impedance; and
causing a phase shift between the source and the load that permits a second predetermined value of the dynamically varying load impedance to be matched to the predetermined source impedance by the addition, between the source and the load, of a single reactive element.

16. The method of claim 15, further comprising:
distinguishing between the dynamically varying impedance of the load being the first predetermined value and the dynamically varying impedance of the load being the second predetermined value;
omitting from an impedance-matching circuit the single reactive element between the source and the load when the dynamically varying impedance of the load is the first predetermined value; and
including in an impedance-matching circuit the single reactive element between the source and the load when the dynamically varying impedance of the load is the second predetermined value.

17. The method of claim 15, wherein the single reactive element is added in a shunt configuration.

18. The method of claim 15, wherein the single reactive element is added in a series configuration.
